(19) United States
(12) Patent Application Publication
(10) Pub. No.: US 2022/0134504 A1
(43) Pub. Date: May 5, 2022

(54) WAFER GRINDING METHOD

(71) Applicant: DISCO CORPORATION, Tokyo (JP)

(72) Inventors: Tetsuo KUBO, Tokyo (JP); Hidekazu NAKAYAMA, Tokyo (JP)

(21) Appl. No.: 17/449,489

(22) Filed: Sep. 30, 2021

(30) Foreign Application Priority Data
Oct. 29, 2020 (JP) 2020-181249

(51) Int. Cl. B24B 7/24

(52) U.S. Cl. CPC B24B 7/241

(57) ABSTRACT

A wafer grinding method includes a step of holding a wafer on a holding surface of a chuck table, a first grinding step of controlling a grinding feeding mechanism by a control unit so as to increase or decrease a load value measured by a load measuring unit and grinding the wafer to a thickness not reaching a predetermined finished thickness of the wafer, and a second grinding step of imparting a preset load value and grinding the wafer until the predetermined finished thickness is reached, after the first grinding step.

### BACKGROUND OF THE INVENTION

### Field of the Invention

The present invention relates to a wafer grinding method for grinding a workpiece such as a semiconductor wafer.

### Description of the Related Art

For example, a grinding apparatus for grinding, by a grindstone, a wafer held on a holding surface of a chuck table as disclosed in Japanese Patent Laid-open No. 2013-226625 grinds the wafer by pressing the grindstone against the wafer. When a grinding speed at which the grindstone is made to approach the wafer is increased, the force with which the grindstone is pressed against the wafer is increased, realizing a shorter grinding time.

However, since the force with which the grindstone is pressed against the wafer is large, a damage layer in which cracks are formed in a layer form in the depth direction from a ground surface of the wafer is formed. In addition, for example, when grinding a wafer made from a hard material such as sapphire, the grindstone may be reciprocally moved upward and downward to grind the wafer while the damage layer is formed at the ground surface of the wafer, thereby seeking shortening of the grinding time, as disclosed in Japanese Patent Laid-open No. 2013-226625.

### SUMMARY OF THE INVENTION

However, since the damage layer exerts a bad influence on devices formed on a surface on the side opposite to the ground surface of the wafer, it is desired that the damage layer of the wafer that has undergone grinding be smaller.

Accordingly, it is an object of the present invention to provide a wafer grinding method by which grinding time can be shortened and the damage layer of the wafer that has undergone grinding can be reduced.

In accordance with an aspect of the present invention, there is provided a wafer grinding method using a grinding apparatus including a chuck table that holds a wafer on a holding surface, a grinding unit that grinds the wafer held on the holding surface by a grindstone, a grinding feeding mechanism that puts the chuck table and the grinding unit into relative grinding feeding in a direction perpendicular to the holding surface, a load measuring unit that measures a load received by the chuck table or the grinding unit when the grindstone is pressed against the wafer held on the holding surface, and a control unit that controls the grinding feeding mechanism on the basis of the load measured by the load measuring unit, the wafer grinding method including a holding step of holding the wafer on the holding surface; a first grinding step of controlling the grinding feeding mechanism by the control unit so as to increase or decrease the load value measured by the load measuring unit and grinding the wafer to a thickness not reaching a predetermined finished thickness; and a second grinding step of imparting a preset load value and grinding the wafer by the grindstone until the predetermined finished thickness is reached, after the first grinding step.

Preferably, in the first grinding step, a difference between the increase and the decrease of the load value measured is reduced as the thickness of the wafer becomes smaller.

According to the grinding method of the present invention, the first grinding step of controlling the grinding feeding mechanism is controlled by the control unit so as to increase or decrease the load value measured by the load measuring unit and grinding the wafer to a thickness not reaching a predetermined finished thickness while being formed with the damage layer is conducted; therefore, grinding time can be shortened before the thickness not reaching the finished thickness is reached. Further, after the first grinding step, the second grinding step of imparting a preset load value, or a fixed load value, and grinding the wafer to reach a predetermined finished thickness is conducted, so as not to newly form the damage layer but to remove the damage layer; by this, the wafer can be made to reach the predetermined finished thickness speedily, and the damage layer of the wafer that has undergone grinding can be reduced.

In addition, in the first grinding step of the wafer grinding method of the present invention, the difference between the increase and the decrease of the load value measured is reduced as the thickness of the wafer becomes smaller, whereby the wafer can be made to reach the predetermined finished thickness more speedily and the damage layer of the wafer that has undergone grinding can be reduced more.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting an example of a grinding apparatus;

FIG. 2 is a graph depicting the relation between grinding time, height of a grinding unit, and grinding feeding speed in a wafer grinding method according to the present invention; and

FIG. 3 depicts a graph for explaining a state in which, in a first grinding step, the difference between the increase and the decrease of a load value exerted on a wafer on a unit time basis is reduced as the thickness of the wafer becomes smaller and a graph for explaining a state in which the difference between the increase and the decrease of the load value exerted on the wafer on a unit time basis is the same even as the thickness of the wafer becomes smaller.

### DETAILED DESCRIPTION OF THE PREFERRED EMBODIMENT

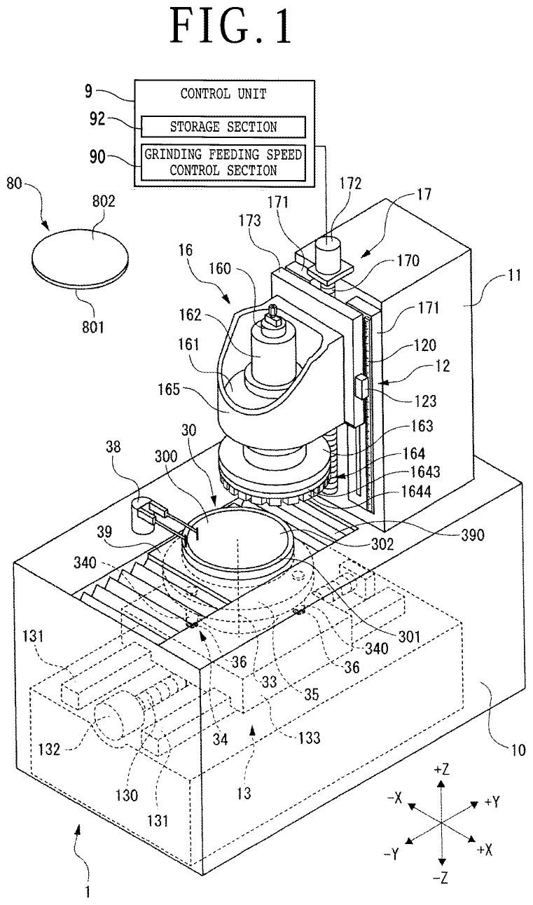

A grinding apparatus 1 depicted in FIG. 1 is an apparatus for grinding a wafer 80 held under suction on a holding surface 302 of a chuck table 30 by a grinding unit 16. In the grinding apparatus 1, a front side (−Y direction side) over an apparatus base 10 of the grinding apparatus 1 is an attachment/detachment region where the wafer 80 is attached onto and detached from the chuck table 30, and a rear side (+Y direction side) over the apparatus base 10 is a processing region where grinding of the wafer 80 held on the chuck table 30 is conducted by the grinding unit 16.

Note that the grinding apparatus used in the grinding method for the wafer 80 according to the present invention is not limited to the grinding apparatus in which the grinding unit 16 is of a single axis such as the grinding apparatus 1, and may be a two-axis grinding apparatus in which a rough grinding unit and a finish grinding unit are provided and the wafer 80 can be positioned on the lower side of the rough grinding unit or the finish grinding unit by a rotating turntable, or the like.

The wafer 80 depicted in FIG. 1 is, for example, a circular semiconductor wafer with sapphire, which is a material difficult to grind, as a parent material, and a plurality of unillustrated streets are set to be orthogonal to one another on a front surface 801 directed downward of the wafer 80. In each of the regions partitioned by the unillustrated streets, unillustrated devices are formed respectively. Note that the configuration of the wafer 80 is not limited to the example depicted in the present embodiment. For example, the wafer 80 may be configured by glass, gallium arsenide, silicon, ceramic, resin, gallium nitride, silicon carbide, or the like.

The chuck table 30 includes, for example, a suction section 300 including a porous material or the like for holding the wafer 80 under suction and a frame body 301 supporting the suction section 300. The suction section 300 communicates with an unillustrated suction source such as an ejector mechanism or a vacuum generating device, and a suction force generated by suction of the unillustrated suction source is transmitted to a holding surface 302 including an exposed surface of the suction section 300 and an upper surface of the frame body 301, whereby the wafer 80 can be held under suction on the holding surface 302 of the chuck table 30. The holding surface 302 is an extremely gentle conically inclined surface that cannot be recognized by visual inspection, with a rotational center of the chuck table 30 as an apex.

As depicted in FIG. 1, the chuck table 30 has an axial direction in a Z-axis direction (vertical direction), is rotatable around a rotational axis 33 passing through the center of the holding surface 302, while being surrounded by a cover 39, and can be reciprocally moved in the Y-axis direction on the apparatus base 10 by a horizontal moving mechanism 13 disposed on the lower side of the cover 39 and a bellows cover 390 connected to the cover 39 and contracted and extended in the Y-axis direction.

The horizontal moving mechanism 13 that moves the chuck table 30 in a horizontal direction (Y-axis direction) parallel to the lower surfaces of grindstones 1644 of the grinding unit 16 includes a ball screw 130 having an axis in the Y-axis direction, a pair of guide rails 131 disposed in parallel to the ball screw 130, a motor 132 that is connected to one end of the ball screw 130 and rotates the ball screw 130, and a movable plate 133 having inside a nut in screw engagement with the ball screw 130 and having bottom portions in sliding contact with the guide rails 131. When the ball screw 130 is rotated by the motor 132, the movable plate 133 is attendantly moved in the Y-axis direction while being guided by the guide rails 131, and the chuck table 30 disposed over the movable plate 133 through a table base 35 can be moved in the Y-axis direction. Note that the horizontal moving mechanism 13 may be a turntable on an upper surface of which a plurality of chuck tables 30 are disposed.

The chuck table 30 is rotatably mounted on the table base 35 which is circular in plan view, and the chuck table 30 is disposed over the movable plate 133 through the table base 35. In addition, the table base 35 is adjustable in inclination by a plurality of adjusting mechanisms 34 disposed at regular intervals in the circumferential direction of the chuck table 30. With the inclination of the table base 35 adjusted, the inclination of the holding surface 302 of the chuck table 30 united with the table base 35 relative to the lower surfaces of the grindstones 1644 of the grinding unit 16 can be adjusted.

The inclination adjusting mechanism 34 in the present embodiment includes, for example, two lifting sections 340 disposed at an interval of 120 degrees in the circumferential direction of the chuck table 30 and one unillustrated fixed column section disposed at an interval of 120 degrees in the circumferential direction from the lifting sections 340. The two lifting sections 340 are, for example, electric actuators capable of vertically moving a part of the table base 35 in the Z-axis direction.

The grinding apparatus 1 includes load measuring units 36 including a load sensor or the like for measuring, for example, a load received by the chuck table 30 when the grindstones 1644 are pressed against the wafer 80 held on the holding surface 302 of the chuck table 30. In the present embodiment, the three load measuring units 36 are each disposed in a state of being clamped from upper and lower sides by the two lifting sections 340 and the one unillustrated fixed column section and the movable plate 133, and are located at intervals of 120 degrees in the circumferential direction of the chuck table 30, that is, located respectively at the apexes of a virtual regular triangle in a horizontal plane. The load measuring unit 36 supports the chuck table 30 through the lifting sections 340 or the unillustrated fixed column section and the table base 35, and receives and detects the load exerted from a +Z direction on the chuck table 30 holding under suction the wafer 80, that is, the load exerted on the wafer 80. The load measuring unit 36 includes, for example, a thin type force sensor made by Kistler Group which uses lead zirconate titanate (PZT) or the like.

Note that a configuration in which the load measuring unit 36 is disposed not on the chuck table 30 side but on the grinding unit 16 side and measures the load received by the grinding unit 16 when the grindstones 1644 are pressed against the wafer 80 held on the holding surface 302 of the chuck table 30 may be adopted. In this case, the three load measuring units 36 are disposed, for example, between a holder 165 of the grinding unit 16 and a housing 161 supported by the holder 165, while located at intervals of 120 degrees in the circumferential direction of the grindstones 1644, that is, located respectively at apexes of a regular triangle, so as to be clamped from both sides in the Z-axis direction.

A column 11 is erected in the processing region, and a grinding feeding mechanism 17 for putting the chuck table 30 and the grinding unit 16 into relative grinding feeding in a direction (Z-axis direction) perpendicular to the holding surface 302 is disposed on the front side on a −Y direction side of the column 11. The grinding feeding mechanism 17 includes a ball screw 170 whose axial direction is in the Z-axis direction, a pair of guide rails 171 disposed in parallel to the ball screw 170, a lifting motor 172 being connected to an upper end of the ball screw 170 and rotating the ball screw 170, and a lifting plate 173 having inside a nut in screw engagement with the ball screw 170 and having side portions in sliding contact with the guide rails 171. With the ball screw 170 rotated by the lifting motor 172, the lifting plate 173 is attendantly reciprocally moved in the Z-axis direction while being guided by the guide rails 171, and the grinding unit 16 fixed to the lifting plate 173 is put into grinding feeding in the Z-axis direction.

For example, the grinding apparatus 1 includes a height position detecting unit 12 that detects the height position of the grinding unit 16 vertically moved in the Z-axis direction by the grinding feeding mechanism 17. The height position detecting unit 12 includes a scale 120 extending in the Z-axis direction along the pair of guide rails 171 and a reading section 123 which is fixed to the lifting plate 173, is moved together with the lifting plate 173 along the scale 120, and optically reads the graduations of the scale 120.

The grinding unit 16 for grinding the wafer 80 held on the holding surface 302 of the chuck table 30 includes, for example, a rotary shaft 160 having an axial direction in the Z-axis direction and having the center of the grindstones 1644 as an axis, a housing 161 that supports the rotary shaft 160 in a rotatable manner, a motor 162 that drives the rotary shaft 160 in a rotational manner, an annular mount 163 connected to a lower end of the rotary shaft 160, a grinding wheel 164 detachably mounted to a lower surface of the mount 163, and a holder 165 that supports the housing 161 and is fixed to the lifting plate 173 of the grinding feeding mechanism 17.

The grinding wheel 164 includes a wheel base 1643 and a plurality of grindstones 1644 disposed in an annular pattern on a bottom surface of the wheel base 1643. In the present embodiment, the grindstones 1644 are formed by binding diamond abrasive grains or the like by a predetermined bond and are segment grindstones in which a plurality of substantially rectangular parallelepiped grindstone chips are arranged on a lower surface of the wheel based 1643, in an annular pattern with predetermined spacing between the grindstone chips. Note that the grindstones 1644 may be in a continuous arrangement in which no spacing is present between the grindstone chips.

In the inside of the rotary shaft 160, an unillustrated channel communicating with a grinding water supply source and serving as a passage of grinding water is provided in the manner of penetrating the rotary shaft 160 in the axial direction (Z-axis direction) of the rotary shaft 160. The unillustrated channel further passes through the mount 163, and is opened in a bottom surface of the wheel base 1643 so as to be able to jet the grinding water toward the contact parts between the grindstones 1644 and the wafer 80.

At a position adjacent to the grinding unit 16 that is in the state of being lowered to a grinding position, for example, a thickness measuring unit 38 for measuring the thickness of the wafer 80 on a contact-type basis is disposed. The thickness measuring unit 38 measures the height position of the holding surface 302 serving as a reference surface by a first linear gauge, measures the height position of a back surface 802 of the wafer 80 to be ground, by a second linear gauge, and calculates the difference between the measurement values obtained by the two linear gauges, whereby the thickness of the wafer 80 can be successively measured during grinding. Note that the thickness measuring unit 38 may be of a non-contact type.

The grinding apparatus 1 includes a control unit 9 capable of controlling each of the component elements of the grinding apparatus 1 described as above. The control unit 9 including a central processing unit (CPU), a storage section 90 such as a memory, and the like is electrically connected, for example, to the grinding feeding mechanism 17, the grinding unit 16, the horizontal moving mechanism 13, and the like. Under the control of the control unit 9, a grinding feeding operation of the grinding unit 16 by the grinding feeding mechanism 17, a rotating operation of the grinding wheel 164 by the grinding unit 16, a positioning operation of the chuck table 30 holding the wafer 80 relative to the grinding wheel 164 by the horizontal moving mechanism 13, and the like are controlled.

When a predetermined amount of operation signals are supplied from an output interface of the control unit 9 functioning also as a servo amplifier to the lifting motor 172, the ball screw 170 is rotated by a predetermined amount, and the control unit 9 can successively recognize the height of the grinding unit 16 put into grinding feeding by the grinding feeding mechanism 17, and can control the grinding feeding speed of the grinding unit 16. Note that a configuration in which the control unit 9 receives height position information concerning the grinding unit 16 that is detected by the height position detecting unit 12 and can successively recognize the height of the grinding unit 16 on the basis of the information may be adopted.

In addition, information concerning the loads measured by the three load measuring units 36 during execution of grinding is sent to the control unit 9, and a total value of the three measurement values is recognized as a load exerted on the wafer 80.

Each of steps in the case where the grinding method for the wafer 80 according to the present invention is carried out using the grinding apparatus 1 depicted in FIG. 1 will be described below.

### (1) Holding Step

First, the wafer 80 is mounted on the holding surface 302 in a state in which the back surface 802 on the side opposite to the front surface 801 which is the device surface is directed upward, such that the center of the holding surface 302 of the chuck table 30 positioned in the attachment/detachment region coincides with the center of the wafer 80. Then, a suction force generated by an operation of the unillustrated suction source is transmitted to the holding surface 302, whereby the wafer 80 is held by the chuck table 30. In addition, the inclinations of the table base 35 and the chuck table 30 are adjusted by the inclination adjusting mechanism 34 depicted in FIG. 1 such that the holding surface 302 which is a gently conically inclined surface becomes parallel to the grinding surfaces (lower surfaces) of the grindstones 1644 of the grinding unit 16 depicted in FIG. 1, whereby the back surface 802 of the wafer 80 held under suction along the holding surface 302 which is a conically inclined surface is made to be substantially parallel to the lower surfaces of the grindstones 1644.

### (2) First Grinding Step

Next, a first grinding step in which the control unit 9 controls the grinding feeding mechanism 17 so as to increase or decrease the load values measured by the load measuring units 36 and the wafer 80 is ground to a thickness not reaching a predetermined finished thickness of the wafer 80 is carried out. Then, in the first grinding step in the present embodiment, the difference between the increase and the decrease of the load values measured by the load measuring units 36 is reduced as the thickness of the wafer 80 becomes smaller, and the load values are converged to a predetermined load value that is to be finally exerted at the time of finishing of the first grinding step. Note that, in the first grinding step, the difference between the increase and the decrease of the load value exerted on the wafer 80 may not be reduced as the thickness of the wafer 80 is made smaller by grinding.

Specifically, the chuck table 30 with the wafer 80 held under suction thereon is fed in the +Y direction by the horizontal moving mechanism 13, whereby positioning is conducted such that the rotational center of the grindstones 1644 is deviated by a predetermined distance in a horizontal direction from the center of the holding surface 302 of the chuck table 30 (namely, the center of the back surface 802 of the wafer 80) and that the rotational track of the grindstones 1644 passes through the rotational center of the wafer 80.

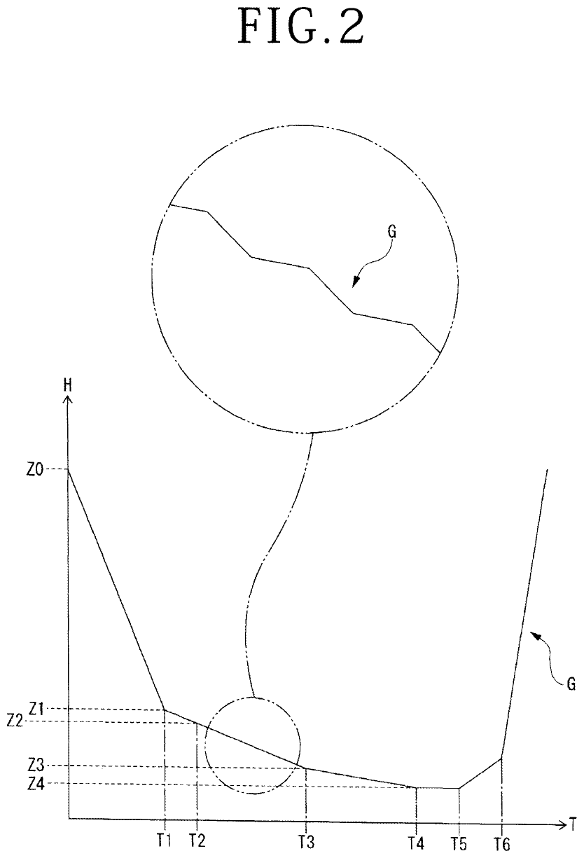

Next, under the control of the grinding feeding mechanism 17 depicted in FIG. 1 by the control unit 9, the grinding unit 16 is put into grinding feeding at a predetermined grinding feeding speed in the −Z direction in which the grindstones 1644 approach the holding surface 302. Specifically, as depicted by graph G of FIG. 2, for example, the grinding unit 16 located at an origin height position Z0 is lowered at high speed. In addition, the height position of the grinding unit 16 started to be lowered from the origin height position Z0 is always recognized by the control unit 9 depicted in FIG. 1.

Then, as depicted by graph G of FIG. 2, the lower surfaces (grinding surfaces) of the grindstones 1644 of the grinding unit 16 reach an air-cut starting position Z1. Note that, in graph G of FIG. 2, the axis of abscissas represents grinding time T, and the axis of ordinates represents the height position H of the lower surfaces of the grindstones 1644 of the grinding unit 16.

When the grinding surfaces of the grindstones 1644 reach the air-cut starting position Z1, such control that the grinding feeding mechanism 17 causes the air-cut feeding speed in an air cut (air-cut from time T1 to time T2 depicted in graph G of FIG. 2) starting from the air-cut starting position Z1 and continuing until the grinding surfaces of the grindstones 1644 come into contact with the back surface 802 of the wafer 80 to be lower than the lowering speed used prior to reaching the air-cut starting position Z1, for example, to be comparable to the initial grinding feeding speed at the time of start of grinding, is conducted under the control unit 9. By performing the air cut, the grindstones 1644 are prevented from thrusting to the wafer 80 at such a speed as to break the wafer 80.

Thereafter, when the grinding surfaces of the grindstones 1644 are lowered to a height position Z2 depicted in graph G, for example, the grinding surfaces of the grindstones 1644 of FIG. 1 rotated counterclockwise as viewed from the +Z direction side come into contact with the back surface 802 of the wafer 80, whereby grinding of the back surface 802 is started. In addition, since the wafer 80 held on the holding surface 302 is also rotated attendant on the rotation of the chuck table 30 at a predetermined rotational speed, for example, counterclockwise as viewed from the +Z direction side, the grindstones 1644 perform grinding of the whole area of the back surface 802 of the wafer 80. Since the wafer 80 is held under suction along the holding surface 302 which is a gentle conically inclined surface of the chuck table 30, in a radial region of the holding surface 302 parallel to the lower surfaces of the grindstones 1644, the grindstones 1644 make contact with the wafer 80, and perform grinding while exerting a predetermined pressing load on the wafer 80. During grinding, grinding water is supplied to contact parts between the grindstones 1644 and the back surface 802 of the wafer 80, whereby the contact parts are cooled and cleaned.

In the first grinding from time T2 to time T3 depicted in graph G of FIG. 2, the control unit 9 controls the grinding feeding speed of the grinding unit 16 by the grinding feeding mechanism 17 so as to increase or decrease the load values measured by the load measuring units 36 depicted in FIG. 1. Specifically, the three load measuring units 36 depicted in FIG. 1 are working point parts of the loads in the −Z direction exerted from the grinding unit 16 side on the chuck table 30 side when grinding is performed; each of the load measuring units 36 is disposed on the chuck table 30 side in a state of being compressed to a certain extent with a predetermined compression pressure (given pressure) exerted on the piezoelectric element. Then, the load measuring unit 36, by receiving the load, generates a plus voltage, for example. The voltage signals representing the loads are transmitted to the control unit 9, so that the control unit 9 can recognize the load (total value of measurement values obtained by the three load measuring unit 36) exerted on the wafer 80.

A program for controlling the grinding feeding speed of the grinding unit 16 by the grinding feeding mechanism 17 is stored in the storage section 90 of the control unit 9, and the program is executed by a grinding feeding speed control section 92 of the control unit 9. For example, the grinding feeding mechanism 17 is controlled in the first grinding step such that the load value exerted from the grinding unit 16 on the wafer 80 is increased or decreased, and the increase or decrease of the load value measured is gradually reduced as the thickness of the wafer 80 becomes smaller, to set a predetermined load value that is to be finally exerted at the time of finishing the first grinding step, in the present embodiment, to a preset load value F_{b}(N) to be exerted on the wafer 80 in the second grinding step described later. Note that the predetermined load value obtained by converging the increase or decrease of the load value to be exerted finally on the wafer 80 at the time of finishing the first grinding step and the preset load value to be exerted on the wafer 80 in the second grinding step may not be the same, and, at least, the preset load value to be exerted on the wafer 80 in the second grinding step is smaller than the load value exerted on the wafer 80 on average in the first grinding step.

The grinding feeding speed of the grinding unit 16 when the grinding surfaces of the grindstones 1644 are lowered to the height position Z2 depicted in graph G of FIG. 2 and start grinding the back surface 802 of the wafer 80 is made to be an initial grinding feeding speed V₀ (μm/s). Further, in the first grinding step, an upper limit permissible of the grinding feeding speed when the grinding feeding speed of the grinding unit 16 is increased is made to be a maximum grinding feeding speed Vₘₐₓ (μm/s).

The load values measured by the load measuring units 36 during the first grinding step are transmitted to the control unit 9, and the load (the total of the measurement values obtained by the three load measuring units 36) being exerted on the wafer 80 recognized by the grinding feeding speed control section 92 is made to be a current measured load value Fₖ (N)=measured load value (sum). Here, k=0, 1, 2, 3, . . . . Note that, in the case where the total of the measurement values obtained by the three load measuring units 36 is 0 N, the calculation in formula (1) described later is not performed. The current measured load value Fₖ is a measured value measured on a unit time basis.

In addition, the current grinding feeding speed of the grinding unit 16 recognized by the control unit 9 in controlling the lifting motor 172 of the grinding feeding mechanism 17 is made to be a current grinding feeding speed Vₖ (μm/s). Besides, a grinding feeding speed intended to be used next as the grinding feeding speed of the grinding unit 16 following the current grinding feeding speed Vₖ is made to be a next-time grinding feeding speed Vₖ₊₁ (μm/s).

In addition, an index used in formula (1) described later that enables adjustment of variation of the grinding feeding speed or absence of variation is made to be index n. For example, the index n is in the range of 0≤n≤5. By setting the value of the index n to an appropriate value (n=1.8), in the present embodiment, while the load value exerted from the grinding unit 16 on the wafer 80 is increased or decreased by controlling of the grinding feeding mechanism 17 in the first grinding step and while the difference between the increase and the decrease of the load value exerted on the wafer 80 is reduced as the thickness of the wafer 80 becomes smaller, the load value can be converged to the predetermined load value to be finally exerted on the wafer 80 at the time of finishing the first grinding step (in the present embodiment, the same value as the set load value F_{b} preset in the second grinding step).

Note that the set load value F_{b}, the initial grinding feeding speed V₀, the maximum grinding feeding speed Vₘₐₓ, and the index n are values set, on a set basis, in the grinding feeding speed control section 92 for each process determined according to the kind and initial thickness of the wafer 80, a grinding removal amount, and the like.

In the present embodiment, for example,

Set load value F_{b} (N): 100 N

Initial grinding feeding speed V₀ (μm/s): 15 μm/s

Maximum grinding feeding speed Vₘₐₓ (μm/s):20 μm/s

Index n: 1.8

The grinding feeding speed control section 92 executes the following formula (1).

Calculated Vₛ=Vₖ×(|F_{b}/Fₖ|)ⁿ Formula (1)

Further, the grinding feeding speed control section 92, in the case where the calculated Vs is

Vₛ≥Vₘₐₓ, determines that Vₖ₊₁=Vₘₐₓ,

and in the case where calculated Vₛ is

Vₛ≤Vₘₐₓ, determines that Vₖ₊₁=Vₛ.

For example, it is assumed that grinding of the back surface 802 of the wafer 80 is started in the first grinding step and that the total load value Fₖ first measured by the three load measuring units 36=current measured load value F₁ is 150 N. Since the current grinding feeding speed Vₖ=current grinding feeding speed V₁=initial grinding feeding speed V₀=15 μm/s and the set load value F_{b}=100 N, the calculated value Vₛ=(15 μm/s)×(|100 N/150 N|)^{1.8}=7.23 μm/s is calculated by the grinding feeding speed control section 92. Since the calculated value Vₛ=7.23 μm/s≤Vₘₐₓ=20 μm/s, the grinding feeding speed control section 92 determines that next-time grinding feeding speed Vₖ₊₁=next-time grinding feeding speed V₂=calculated value Vₛ=7.23 μm/s.

By the control of the lifting motor 172 by the control unit 9 depicted in FIG. 1, the grinding feeding speed of the grinding unit 16 is reduced from the current grinding feeding speed V₁ (μm/s)=initial grinding feeding speed V₀ (μm/s)=15 μm/s to the next-time grinding feeding speed V₂=7.23 μm/s, and, attendant on this, the load value to be exerted on the wafer 80 is decreased. Note that the decreased load value is, for example, 72.3 N.

After unit time has elapsed after the load value to be exerted on the wafer 80 is decreased from the current measured load value F₁=150 N to 72.3 N as described above, the current measured load value F₂ measured by the three load measuring units 36 (the measured load value at the second time) becomes 72.3 N, and the measurement information is sent to the control unit 9. Then, since the current grinding feeding speed V₂=7.23 μm/s and the set load value F_{b}=100 N, a calculated value Vₛ=(7.23 μm/s)×(|100 N/72.3 N|)^{1.8}=12.96 μm/s is calculated by the grinding feeding speed control section 92. Since the calculated value Vₛ=12.96 μm/s≤Vₘₐₓ=20 μm/s, the grinding feeding speed control section 92 determines that the next-time grinding feeding speed Vₖ₊₁=next-time grinding feeding speed V₃=calculated value Vₛ=12.96 μm/s.

By the control of the lifting motor 172 by the control unit 9, the grinding feeding speed of the grinding unit 16 is increased from the current grinding feeding speed V₂=7.23 μm/s to the next-time grinding feeding speed V₃=12.96 μm/s, and, attendant on this, the load value to be exerted on the wafer 80 is increased. Note that increased load value is, for example, 129.6 N.

In this way, the control unit 9 controls the grinding feeding mechanism 17 so as to increase or decrease the load values measured by the load measuring units 36 depicted in FIG. 1, the measurement of the thickness of the wafer 80 to be ground is successively conducted on a unit time basis by the thickness measuring unit 38, and, while the measurement information is sent to the control unit 9, the wafer 80 is gradually ground to a thickness not reaching a predetermined finished thickness.

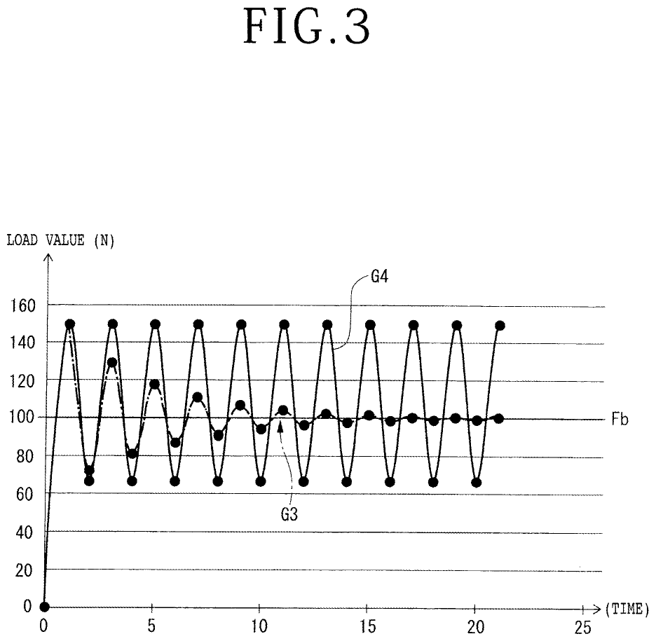

FIG. 3 depicts the measured load value in the case where the index n=1.8 as graph G3 of a dot-dash line, and depicts the measured load value in the case where the index n=2 as graph G4 of solid line. By setting the index n to an appropriate value (in the present embodiment, n=1.8), the control unit 9 can perform such control as to increase or decrease the load value to be exerted on the wafer 80 as depicted in graph G3, and to reduce the difference between the increase and the decrease (the difference between the increased load value exerted at the precedent time and the decreased load value being exerted at present time) of the load value as the wafer 80 becomes thinner. Note that, in the present embodiment, the difference between the increase and the decrease of the load value measured is reduced as the thickness of the wafer 80 becomes smaller in the first grinding step, but the first grinding step may be carried out such that the index n in the formula (1) is 2 and, as depicted in graph G4 of FIG. 3, a fixed width may appear, that is, for example, an increased load of 150 N and a decreased load of 66.7 N are alternately exerted on the wafer 80. In either case of the case where the index n=1.8 or the case where the index n=2, the wafer 80 is ground such that an easily grindable damage layer is formed in the first grinding step, and the wafer 80 is ground in a shorter period of time as compared to the case where it is ground by the grinding unit 16 fed at a fixed grinding feeding speed.

In addition, in the present embodiment, by setting the index n=1.8, while the load value to be exerted on the wafer 80 is increased or decreased, the predetermined load value to be finally exerted on the wafer 80 at the time of finishing the first grinding step is brought to be closer to the preset load value F_{b}=100 N to be exerted on the wafer 80 in the second grinding step described later, such that the difference between the increase and the decrease of the load measured is reduced as the thickness of the wafer 80 becomes smaller.

Note that the predetermined load value that is to be finally exerted on the wafer 80 by being converged while being increased or decreased in the first grinding step may be the same as, or may be different from, the preset load value to be exerted on the wafer 80 in the second grinding step.

The measurement of the thickness of the wafer 80 to be ground is successively conducted on a unit time basis by the thickness measuring unit 38 depicted in FIG. 1, and the measurement information is sent to the control unit 9. While the control unit 9 monitors whether or not the thickness of the wafer 80 has reached a thickness not reaching a predetermined finished thickness and controls the grinding feeding speed of the grinding unit 16 by the grinding feeding mechanism 17 as described above, the grinding unit 16 is lowered to the height position Z3 depicted in graph G of FIG. 2, whereby the wafer 80 is put into a state of being ground (first grinding from time T2 to time T3 depicted in graph G of FIG. 2) in a shorter period of time as compared to the prior art, to a thickness which is thicker by, for example, several micrometers than the finished thickness preset in the control unit 9. In this state, the damage layer is still remaining on the wafer 80.

### (3) Second Grinding Step

After the first grinding step, the second grinding step in which the preset load value is imparted and the wafer 80 is ground by the grindstones 1644 until reaching the predetermined finished thickness is carried out. In the present embodiment, the preset load value is 100 N, which is the same as the predetermined load value to be finally exerted on the wafer 80 at the time of finishing the first grinding step. Then, during a period from time T3 to time T4 depicted in graph G of FIG. 2, the wafer 80 is subjected to second grinding while a fixed set load of 100 N is exerted on the wafer 80, to a finished thickness preset in the control unit 9, whereby the second grinding step is completed. Note that the set load value may be different from the value set in the first grinding step.

Thereafter, carried out is processing called sparkout in which the lowering of the grinding unit 16 by the grinding feeding mechanism 17 is stopped and the grindstones 1644 being rotated are put into contact with the wafer 80 for a predetermined period of time to grind the wafer 80. In the sparkout from time T4 to time T5 depicted in graph G of FIG. 2, in a state in which the height position of the grinding unit 16 is stopped at the height position Z4 when the second grinding of the wafer 80 is finished, an unground part of the back surface 802 of the wafer 80 being rotated is removed by the rotating grindstones 1644, whereby the back surface 802 is conditioned.

After the sparkout is performed, the grinding unit 16 is subjected to an escape cut (escape cut from time T5 to time T6 depicted in graph G of FIG. 2) by the grinding feeding mechanism 17. In the escape cut, the grinding unit 16 is moved upward slowly for restraining a bad influence on the back surface 802 of the wafer 80 in the case where what is generally called a spring-back phenomenon or the like is generated. Thereafter, the grinding unit 16 is moved upward at high speed to the origin height position Z0, for example.

As described above, the wafer grinding method according to the present invention performs the holding step of holding the wafer 80 on the holding surface 302 of the chuck table 30 and the first grinding step of controlling the grinding feeding mechanism 17 by the control unit 9 such that the load values measured by the load measuring units 36 are increased or decreased, to grind the wafer 80 to a thickness not reaching the predetermined finished thickness while forming the wafer 80 with the damage layer, thereby grinding the wafer 80 to a thickness not reaching the finished thickness in a short period of time by forming the wafer 80 with the damage layer. Further, after the first grinding step, the wafer grinding method performs the second grinding step of grinding the wafer 80 by the grindstones 1644 until the predetermined finished thickness is obtained while imparting a preset load value, namely, a fixed load value, so as not to newly form a damage layer, thereby grinding the wafer 80 so as to remove the damage layer formed in the first grinding step. As a result, it is possible to cause the wafer 80 to reach the predetermined finished thickness in a short period of time and to reduce the damage layer of the wafer 80 after grinding.

In addition, in the wafer grinding method according to the present invention, the first grinding step reduces the difference between the increase and the decrease of the load value measured, as the thickness of the wafer 80 becomes smaller, whereby it is possible to cause the wafer 80 to reach the predetermined finished thickness more speedily, and to further reduce the damage layer of the wafer 80 that has undergone grinding.

The wafer grinding method according to the present invention is not limited to the above embodiments, and it is needless to say that the invention may be carried out with various modifications within the scope of the technical idea thereof. In addition, shapes and the like of each configuration of the grinding apparatus 1 illustrated in the attached drawings are also not limited to those illustrated, and may be modified, as required, within such ranges that the effects of the present invention can be produced.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer grinding method using a grinding apparatus including a chuck table that holds a wafer on a holding surface, a grinding unit that grinds the wafer held on the holding surface by a grindstone, a grinding feeding mechanism that puts the chuck table and the grinding unit into relative grinding feeding in a direction perpendicular to the holding surface, a load measuring unit that measures a load received by the chuck table or the grinding unit when the grindstone is pressed against the wafer held on the holding surface, and a control unit that controls the grinding feeding mechanism on a basis of the load measured by the load measuring unit, the wafer grinding method comprising:
a holding step of holding the wafer on the holding surface;
a first grinding step of controlling the grinding feeding mechanism by the control unit so as to increase or decrease a load value measured by the load measuring unit and grinding the wafer to a thickness not reaching a predetermined finished thickness; and
a second grinding step of imparting a preset load value and grinding the wafer by the grindstone until the predetermined finished thickness is reached, after the first grinding step.

2. The wafer grinding method according to claim 1, wherein, in the first grinding step, a difference between the increase and the decrease of the measured load value is reduced as the thickness of the wafer becomes smaller.
